(19) United States
(12) Patent Application Publication
(10) Pub. No.: US 2017/0114456 A1
(43) Pub. Date: Apr. 27, 2017

(54) APPARATUS AND METHOD FOR TREATING A SUBSTRATE

(71) Applicant: SEMES CO., LTD., Cheonan-si (KR)

(72) Inventors: EUNTARK LEE, Cheonan-si (KR); Jong Seok SEO, Cheonan-si (KR)

(73) Assignee: SEMES CO., LTD., Cheonan-si (KR)

(21) Appl. No.: 15/296,474

(22) Filed: Oct. 18, 2016

(30) Foreign Application Priority Data
Oct. 27, 2015 (KR) 10-2015-0149309

(51) Int. Cl. C23C 16/44; H01L 21/027; C23C 16/455

(52) U.S. Cl. CPC C23C 16/4412; C23C 16/455; H01L 21/0274

(57) ABSTRACT

An apparatus and a method for treating a substrate are disclosed. The apparatus may include a process chamber including an upper chamber and a lower chamber that are coupled to each other to define a treatment space, a supporting unit provided within the treatment space to support a substrate, and an exhausting element configured to exhaust an air from the treatment space or a neighboring region of the treatment space. The exhausting element may include an outer exhausting line connected to an outer exhausting hole, and the outer exhausting hole may be formed in or through the upper or lower chamber and may be connected to a contact surface, at which the upper and lower chambers are in contact with each other.

### CROSS-REFERENCE TO RELATED APPLICATIONS

This U.S. non-provisional patent application claims priority under 35 U.S.C. §119 to Korean Patent Application No. 10-2015-0149309, filed on Oct. 27, 2015, in the Korean Intellectual Property Office, the entire contents of which are hereby incorporated by reference.

### BACKGROUND OF THE INVENTION

The present disclosure relates to an apparatus and a method for treating a substrate, and in particular, to a substrate treatment apparatus configured to supply close-contact gas to a substrate and a method of treating a substrate using the same.

A semiconductor fabrication process may include a photo-lithography process for forming a desired pattern on a wafer. The photo-lithography process is usually performed in a spinner local system that is connected with an exposure system and is configured to perform a coating process, an exposure process, and a developing process in a sequential manner. The spinner system is used to sequentially or selectively perform a hexamethyl disilazane (HMDS) treating process, a coating process, a bake process, and a developing process. The HMDS treating process is performed to improve a close-contact efficiency of a photo-resist (PR) solution and includes supplying HMDS onto a wafer before the coating process of the PR solution. The bake process is performed to strengthen the PR layer formed on the wafer or to adjust a temperature of the wafer to a predetermined temperature and includes heating or cooling the wafer.

FIG. 1 is a diagram illustrating a general apparatus 2 for performing the HMDS treating process. The apparatus 2 has an upper housing 3, a lower housing 4, a sealing element 5, a supporting unit 6, and a gas supplying unit 7. The gas supplying unit 7 is configured to supply an HMDS gas. The HMDS gas is used to change a surface property of the substrate W from hydrophilicity to hydrophobicity. The upper housing 3 and the lower housing 4 are configured to provide a hermetically-sealed chamber space during the HMDS treating process. The use of the sealing element 5 makes it possible to maintain the hermetically-sealed chamber space during the HMDS treating process.

In the step of loading or unloading the substrate W, one of the upper housing 3 and the lower housing 4 is vertically moved to open the chamber space. However, in certain cases, this operation may lead to damage of the sealing element 5 or crack of its neighboring part, and thus, there may be a failure in maintaining the chamber space at the vacuum state during the HMDS treating process. Furthermore, an expensive part is used to maintain the chamber space at a high vacuum state, but in the case where vacuum-related failures occur frequently, vacuum-related parts may be damaged and should be replaced.

In addition, when there is a vacuum-related failure or a part near the sealing element 5 is cracked, an external air may be undesirably supplied into the chamber space and may cause a process failure. Fumes, which are deposited in the crack near the sealing element 5 during the process, may flow into the chamber space, along with the external air, and may cause the process failure. Also, the HMDS gas may be exhausted to the outside of the apparatus 2 through the crack, thereby polluting the environment.

### SUMMARY

Some embodiments of the inventive concept provide a substrate treatment apparatus, which is configured to maintain an internal pressure of a treatment space at a desired level when an HMDS gas is supplied onto a substrate to treat the substrate, and a method of treating a substrate using the same.

Some embodiments of the inventive concept provide a substrate treatment apparatus, which is configured to prevent an external air from flowing into a treatment space, and a method of treating a substrate using the same.

Some embodiments of the inventive concept provide a substrate treatment apparatus, which is configured to prevent an internal gas from being undesirably exhausted to the outside, and a method of treating a substrate using the same.

According to some embodiments of the inventive concept, a substrate treatment apparatus is provided.

In some embodiments, the substrate treatment apparatus may include a process chamber including an upper chamber and a lower chamber that are coupled to each other to define a treatment space, a supporting unit provided within the treatment space to support a substrate, and an exhausting element configured to exhaust an air from the treatment space or a neighboring region of the treatment space. The exhausting element may include an outer exhausting line connected to an outer exhausting hole, and the outer exhausting hole may be formed in or through the upper or lower chamber and may be connected to a contact surface, at which the upper and lower chambers are in contact with each other.

In some embodiments, the substrate treatment apparatus may further include a sealing element that is provided on the contact surface between the upper and lower chambers to hermetically seal the treatment space from an outside. The outer exhausting hole may be formed at an outer position farther from the supporting unit, compared with the sealing element.

In some embodiments, the exhausting element may further include an inner exhausting line connected to an inner exhausting hole. Here, the inner exhausting hole may be formed in or through the upper or lower chamber and may be used to exhaust an air from the treatment space.

In some embodiments, the exhausting element may further include a combined line connected to both of the inner and outer exhausting lines and a decompressing element provided on the combined line.

In some embodiments, the substrate treatment apparatus may further include a heating unit configured to heat the substrate loaded on the supporting unit and a gas supplying unit configured to supply a gas into the treatment space.

In some embodiments, the substrate treatment apparatus may further include a controller controlling the gas supplying unit and the decompressing element. The controller may control the gas supplying unit and the decompressing element so as to maintain the treatment space at a pressure of 50-500 pascal during a process of treating the substrate.

In some embodiments, the gas to be supplied through the gas supplying unit may contain hexamethyldisilazane (HMDS).

According to some embodiments of the inventive concept, the substrate treatment apparatus may include a process chamber including an upper chamber and a lower chamber that are coupled to each other to define a treatment space, a supporting unit provided within the treatment space to support a substrate, an exhausting element configured to exhaust an air from the treatment space or a neighboring region of the treatment space, and a controller controlling the exhausting element. During a process of supplying a hexamethyldisilazane gas, which is used as a close-contact gas, onto the substrate to treat the substrate, the controller may control the exhausting element to maintain the treatment space at a pressure of 50-500 pascal.

In some embodiments, the substrate treatment apparatus may further include a sealing element that is provided on a contact surface, at which the upper and lower chambers are in contact with each other, to hermetically seal the treatment space from an outside. The exhausting element may include an outer exhausting line, which is connected to an outer exhausting hole that is formed in or through the upper or lower chamber and is connected to the contact surface, and an inner exhausting line, which is connected to an inner exhausting hole that is formed in or through the upper or lower chamber and is used to exhaust an air from the treatment space. The outer exhausting hole may be formed at an outer position farther from the supporting unit, compared with the sealing element.

In some embodiments, the exhausting element may further include a combined line connected to both of the inner and outer exhausting lines and a decompressing element provided on the combined line.

In some embodiments, the substrate treatment apparatus may further include a heating unit configured to heat the substrate loaded on the supporting unit and a gas supplying unit configured to supply the hexamethyldisilazane gas into the treatment space.

According to some embodiments of the inventive concept, a method of treating a substrate may be provided.

In some embodiments, the method may include supplying a close-contact gas into a hermetically-sealed treatment space to treat a substrate disposed in the treatment space. Here, the close-contact gas may be a hexamethyldisilazane gas. During the supplying of the close-contact gas, the treatment space or a neighboring region of the treatment space may be decompressed to maintain the treatment space at a pressure of 50-500 pascal.

In some embodiments, the supplying of the close-contact gas may include exhausting an air from the treatment space or a neighboring region of the treatment space. The exhausting of the air from the neighboring region of the treatment space may be performed through an outer exhausting line connected to an outer exhausting hole. Here, the outer exhausting hole may be formed in or through an upper chamber or a lower chamber and may be connected to a contact surface, at which the upper and lower chambers are in contact with each other, and the treatment space may be defined by the upper and lower chambers.

In some embodiments, the exhausting of the air from the treatment space may be performed through an inner exhausting line that is connected to an inner exhausting hole. Here, the inner exhausting hole may be formed in or through the upper or lower chamber.

In some embodiments, the outer exhausting hole may be connected to the contact surface between the upper and lower chambers and may be formed at an outer position farther from the treatment space, compared with a sealing element configured to hermetically seal the treatment space from an outside.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a diagram illustrating a general apparatus for performing an HMDS process.

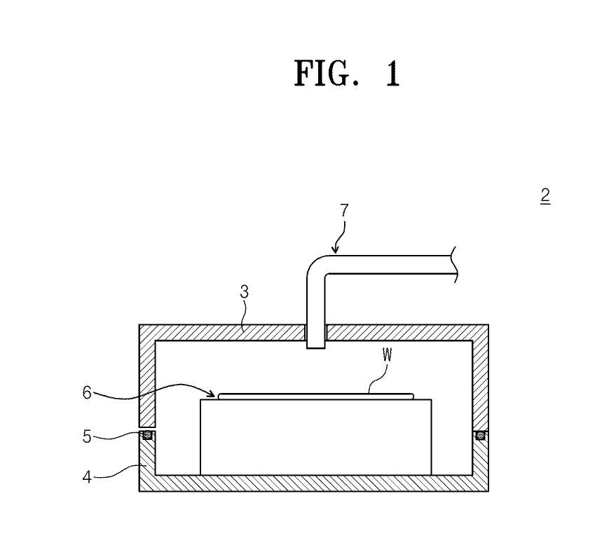

FIG. 2 is a plan view illustrating a substrate treatment apparatus according to some embodiments of the inventive concept.

FIG. 3 is a diagram illustrating a structure of the substrate treatment apparatus that is seen in a direction A-A of FIG. 2.

FIG. 4 is a diagram illustrating a structure of the substrate treatment apparatus that is seen in a direction B-B of FIG. 2.

FIG. 5 is a sectional view illustrating an example of a substrate treatment apparatus provided in a thermal treatment chamber of FIG. 2.

FIG. 6 is a sectional view illustrating another example of the substrate treatment apparatus of FIG. 5.

FIG. 7 is a diagram schematically illustrating a method of controlling a process pressure in a substrate treating process using the substrate treatment apparatus of FIG. 5.

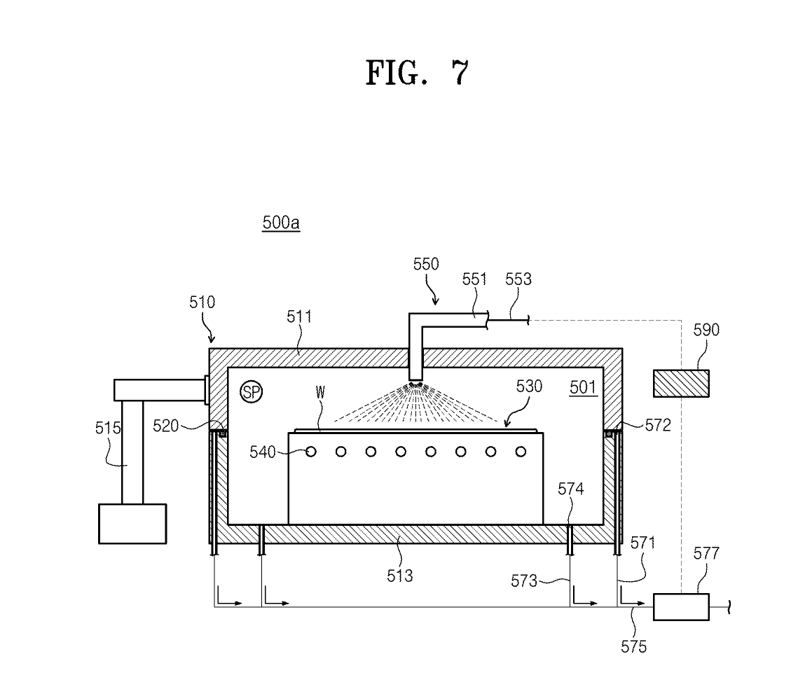

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

An apparatus according to the present embodiment may be used to perform a photolithography process on a substrate (e.g., a semiconductor wafer or a flat display panel). In particular, the apparatus according to the present embodiment may be used to perform a coating or developing process on a substrate.

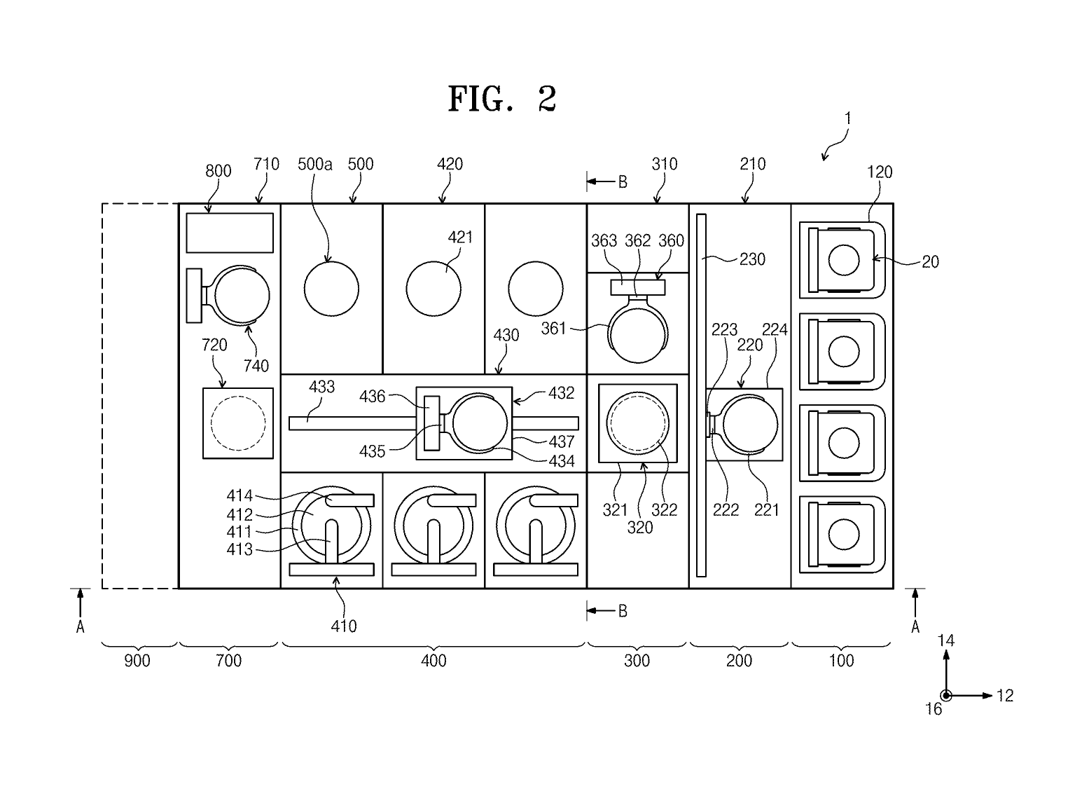

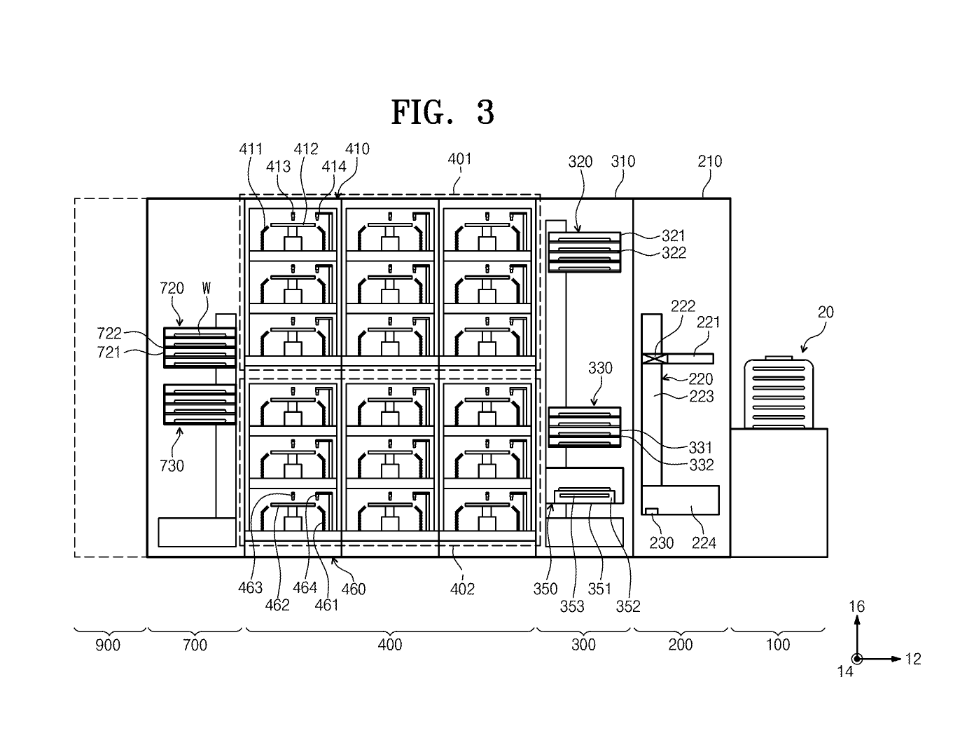

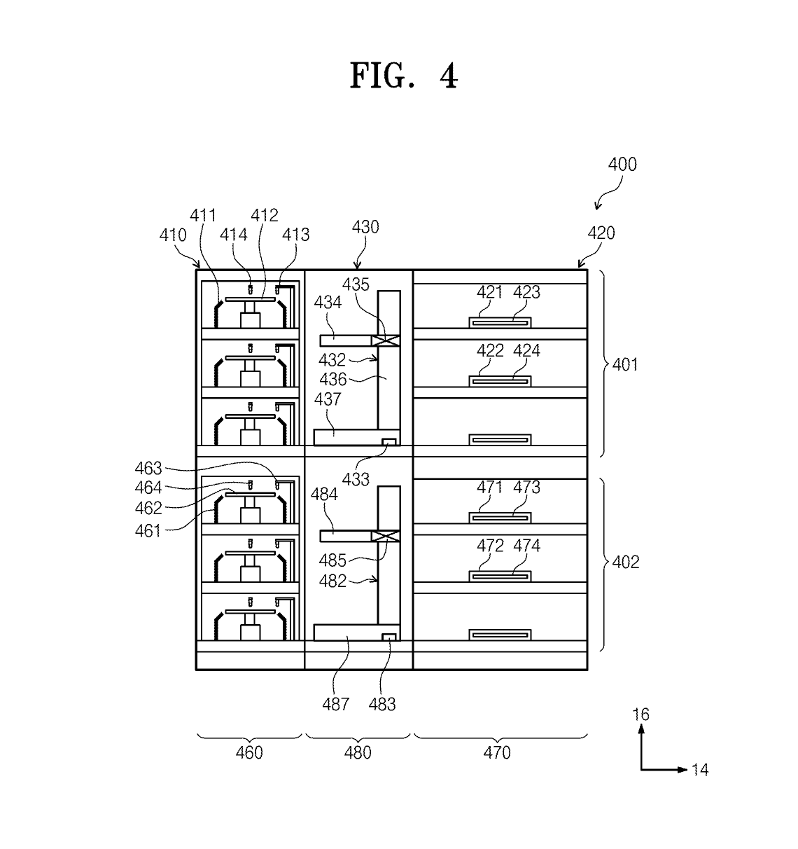

FIGS. 2 to 4 are diagrams schematically illustrating a substrate treatment apparatus according to some embodiments of the inventive concept. FIG. 2 is a top plan view of the substrate treatment apparatus, FIG. 3 is a diagram illustrating a structure of the substrate treatment apparatus that is seen in a direction A-A of FIG. 2, and FIG. 4 is a diagram illustrating a structure of the substrate treatment apparatus that is seen in a direction B-B of FIG. 2.

Referring to FIGS. 2 to 4, a substrate treatment apparatus 1 may include a load port 100, an index module 200, a buffer module 300, a coating and developing module 400, and a purge module 800. The load port 100, the index module 200, the buffer module 300, the coating and developing module 400, and an interface module 700 may be arranged in a sequential and columnar manner. The purge module 800 may be provided in the interface module 700. In certain embodiments, the purge module 800 may be provided at various positions (e.g., at a rear portion of the interface module 700, to which an exposure system is connected, or at a side portion of the interface module 700).

Hereinafter, a direction, in which the load port 100, the index module 200, the buffer module 300, the coating and developing module 400, and the interface module 700 are arranged, will be referred to as a first direction 12. When viewed in a top plan view, a direction perpendicular to the first direction 12 will be referred to as a second direction 14, and a direction perpendicular to the first and second directions 12 and 14 will be referred to as a third direction 16.

A substrate W may be stored in a cassette 20, and when there is a need to move the substrate W, the substrate W may be moved along with the cassette 20. The cassette 20 may be configured to provide a hermetically sealed space. As an example, the cassette 20 may be a front open unified pod (FOUP) with a frontward door.

Hereinafter, the load port 100, the index module 200, the buffer module 300, the coating and developing module 400, the interface module 700, and the purge module 800 will be described in more detail.

The load port 100 may include a loading table 120, which is configured to load the cassette 20 with the substrates W. In some embodiments, the load port 100 may include a plurality of the loading tables 120, which are arranged in a row along the second direction 14. As shown in FIG. 2, four loading tables 120 may be provided in the load port 100, but the inventive concept is not limited thereto.

The index module 200 may be used to transfer the substrate W between the cassette 20, which is loaded on the loading table 120 of the load port 100, and the buffer module 300. The index module 200 may include a frame 210, an index robot 220, and a guide rail 230. The frame 210 may be provided to have a substantially hollow parallelepiped structure and may be provided between the load port 100 and the buffer module 300. The frame 210 of the index module 200 may be provided at a level lower than that of a frame 310 of the buffer module 300 to be described below. The index robot 220 and the guide rail 230 may be provided within the frame 210. A hand 221 may be directly used to handle the substrate W, and the index robot 220 may be configured to allow the hand 221 to have a movable and rotatable structure in the first, second, and third directions 12, 14, and 16. The index robot 220 may include a hand 221, an arm 222, a supporter 223, and a prop 224. The hand 221 may be fixedly connected to the arm 222. The arm 222 may be provided to have a stretchable and rotatable structure. The supporter 223 may be provided to have a longitudinal direction parallel to the third direction 16. The arm 222 may be coupled to the supporter 223 so as to be movable along the supporter 223. The supporter 223 may be fixedly connected to the prop 224. The guide rail 230 may be provided to have a longitudinal direction parallel to the second direction 14. The prop 224 may be coupled to the guide rail 230 so as to be movable along the guide rail 230. Although not shown, a door opener for opening or closing a door of the cassette 20 may be further provided in the frame 210.

The buffer module 300 may include a frame 310, a first buffer 320, a second buffer 330, a cooling chamber 350, and a first buffer robot 360. The frame 310 may be provided to have a hollow parallelepiped structure and may be provided between the index module 200 and the coating and developing module 400. The first buffer 320, the second buffer 330, the cooling chamber 350, and the first buffer robot 360 may be positioned within the frame 310. The cooling chamber 350, the second buffer 330, and the first buffer 320 may be sequentially disposed from the bottom in the third direction 16. The first buffer 320 may be positioned at a level corresponding to that of a coating module 401 of the coating and developing module 400 to be described below, and the second buffer 330 and the cooling chamber 350 may be provided at a level corresponding to that of a developing module 402 of the coating and developing module 400 to be described below. The first buffer robot 360 may be disposed to be spaced apart from the second buffer 330, the cooling chamber 350, and the first buffer 320 by a predetermined distance in the second direction 14.

Each of the first and second buffers 320 and 330 may be configured to temporarily store a plurality of substrates W. The second buffer 330 may include a housing 331 and a plurality of supporters 332. The supporters 332 may be disposed within the housing 331 and may be spaced apart from each other in the third direction 16. Each of the substrates W may be disposed on a corresponding one of the supporters 332. The housing 331 may include openings (not shown) that are formed toward the index robot 220 and the first buffer robot 360 and that allow the index robot 220 and the first buffer robot 360 to load or unload the substrate W on or from the supporter 332 in the housing 331. The first buffer 320 may have a structure that is substantially similar to that of the second buffer 330. However, a housing 321 of the first buffer 320 may be provided to have openings formed toward the first buffer robot 360 and a coating robot 432 of the coating module 401. The number of supporters 322 provided in the first buffer 320 may be equal to or different from that of supporters 332 provided in the second buffer 330. In some embodiments, the number of the supporters 332 provided in the second buffer 330 may be greater than that of the supporters 322 provided in the first buffer 320.

The first buffer robot 360 may be used to transfer the substrate W between the first buffer 320 and the second buffer 330. The first buffer robot 360 may include a hand 361, an arm 362, and a supporter 363. The hand 361 may be fixedly connected to the arm 362. The arm 362 may be provided to have a stretchable structure, allowing the hand 361 to be moved in the second direction 14. The arm 362 may be coupled to the supporter 363 so as to be linearly movable along the supporter 363 or in the third direction 16. The supporter 363 may have a length extending from a position corresponding to the second buffer 330 to a position corresponding to the first buffer 320. The supporter 363 may be further extended in an upward or downward direction. The first buffer robot 360 may be provided to allow the hand 361 to be driven in only the second and third directions 14 and 16 (i.e., in a biaxial driving mode).

The cooling chamber 350 may be used to decrease a temperature of the substrate W. The cooling chamber 350 may include a housing 351 and a cooling plate 352. The cooling plate 352 may have a top surface, on which the substrate W is loaded, and a cooling unit 353 for cooling the substrate W. Various ways (e.g., using a cooling water or a thermoelectric element) may be used to realize the cooling operation of the cooling unit 353. In addition, a lift pin assembly may be provided in the cooling chamber 350 to place the substrate W on the cooling plate 352. The housing 351 may include openings that are formed toward the index robot 220 and a developing robot in the developing module 402 and that allow the index robot 220 and the developing robot to load or unload the substrate W on or from the cooling plate 352. In addition, doors may be provided in the cooling chamber 350 to open or close the openings.

The coating module 401 may be configured to perform a resist coating process of coating the substrate W with a solution of a photosensitive material (e.g., a photoresist material) and a thermal treatment process of heating or cooling the substrate W before or after the resist coating process. The coating module 401 may include a coating chamber 410, a thermal treatment chamber 500, a bake chamber 420, and a transfer chamber 430. The coating chamber 410, the thermal treatment chamber 500, the bake chamber 420, and the transfer chamber 430 may be sequentially disposed in the second direction 14. In some embodiments, the coating module 401 may include a plurality of the coating chambers 410 that are arranged along the first and third directions 12 and 16. A plurality of the bake chambers 420 may be arranged in each of the first direction 12 and the third direction 16.

The transfer chamber 430 may be provided parallel to the first buffer 320 of the first buffer module 300 in the first direction 12. The coating robot 432 and a guide rail 433 may be disposed within the transfer chamber 430. The transfer chamber 430 may have a substantially rectangular structure. The coating robot 432 may be used to transfer the substrate W between the bake chambers 420, the coating chambers 410, and the first buffer 320 of the first buffer module 300. The guide rail 433 may be provided to have a longitudinal direction parallel to the first direction 12. The guide rail 433 may be configured in such a way that the coating robot 432 is linearly moved in the first direction 12. The coating robot 432 may include a hand 434, an arm 435, a supporter 436, and a prop 437. The hand 434 may be fixedly connected to the arm 435. The arm 435 may be provided to have a stretchable structure, allowing the hand 434 to be moved in a horizontal direction. The supporter 436 may be provided to have a longitudinal direction parallel to the third direction 16. The arm 435 may be coupled to the supporter 436 so as to be linearly movable along the supporter 436 or in the third direction 16. The supporter 436 may be fixedly connected to the prop 437, and the prop 437 may be coupled to the guide rail 433 so as to be movable along the guide rail 433.

All of the coating chambers 410 may have the same structure. However, photoresist materials to be used in the coating chambers 410 may be of different kinds. As an example, a chemical amplification resist may be used as the photoresist. The coating chamber 410 may be used to coat the substrate W with the photoresist. The coating chamber 410 may include a housing 411, a supporting plate 412, and a nozzle 413. The housing 411 may have a top-open cup-shaped structure. The supporting plate 412 may be provided within the housing 411 and may be used to support the substrate W. The supporting plate 412 may be provided to have a rotatable structure. The nozzle 413 may be used to supply a photoresist material onto the substrate W loaded on the supporting plate 412. The nozzle 413 may have a circular pipe shape and may be used to supply the photoresist material toward a center of the substrate W. In certain embodiments, the nozzle 413 may have a length corresponding to a diameter of the substrate W and may have a slit-shaped ejecting hole. Furthermore, the coating chamber 410 may further include a nozzle 414 which is configured to supply a cleaning solution (e.g., a deionized water), and here, the cleaning solution may be used to clean a surface of the substrate W coated with the photoresist material.

A substrate treatment apparatus 500a provided in the thermal treatment chamber 500a may be configured to supply a close-contact gas onto a top surface of the substrate W. In some embodiments, the close-contact gas may be, for example, a hexamethyldisilazane (HMDS) gas.

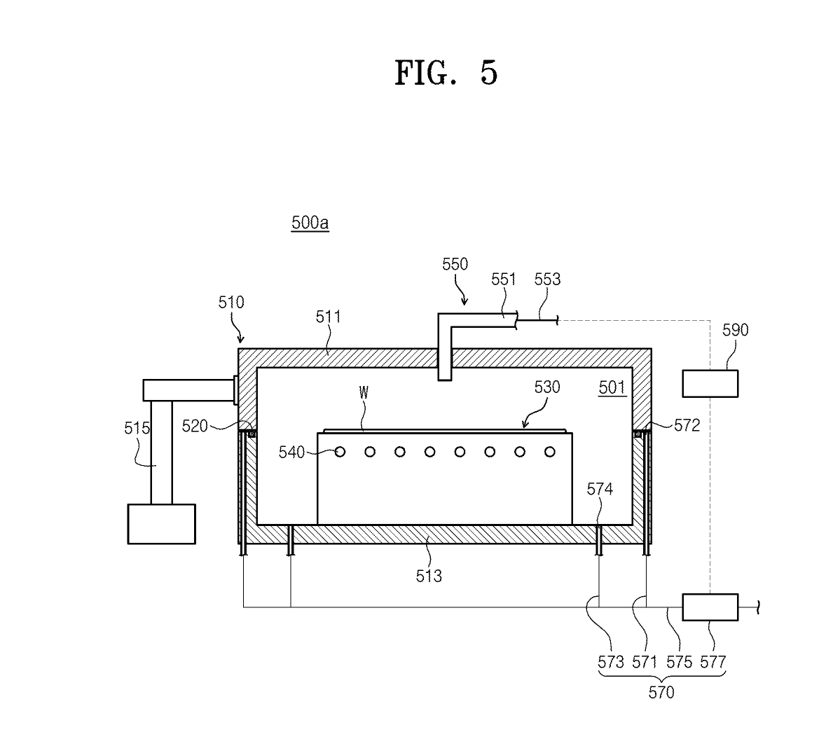

FIG. 5 is a sectional view illustrating a substrate treatment apparatus 500a, which may be provided in the thermal treatment chamber of FIG. 2. Referring to FIG. 5, the substrate treatment apparatus 500a may include a process chamber 510, a sealing element 520, a supporting unit 530, a heating unit 540, a gas supplying unit 550, an exhausting element 570, and a controller 590.

The process chamber 510 may be configured to provide a treatment space 501. The process chamber 510 may be provided to have a circular cylinder shape. In certain embodiments, the process chamber 510 may be provided to have a parallelepiped shape. The process chamber 510 may include an upper chamber 511 and a lower chamber 513. The upper chamber 511 and the lower chamber 513 may be combined with each other to define the treatment space 501.

When viewed in a top plan view, the upper chamber 511 may be provided to have a circular shape. The lower chamber 513 may be positioned below the upper chamber 511. When viewed in a top plan view, the lower chamber 513 may be provided to have a circular shape.

An actuator 515 may be connected to the upper chamber 511. The actuator 515 may be configured to move the upper chamber 511 in a vertical direction. When the substrate W is inserted into the process chamber 510, the upper chamber 511 may be upwardly moved by the actuator 515 to open the process chamber 510. Before a process of treating the substrate W, the upper chamber 511 may be downwardly moved by the actuator 515 until the upper chamber 511 is in contact with the lower chamber 513, and thus, the process chamber 510 may be closed. As described above, the actuator 515 may be connected to the upper chamber 511, but in certain embodiments, the actuator 515 may be connected to the lower chamber 513 and may be used to change a vertical position of the lower chamber 513.

The sealing element 520 may be used to hermetically seal the treatment space 501 from the outside of the process chamber 510. The sealing element 520 may be provided on a contact surface at which the upper and lower chambers 511 and 513 are in contact with each other. As an example, the sealing element 520 may be provided on a contact surface of the lower chamber 513 in contact with the upper chamber 511.

The supporting unit 530 may be configured to support the substrate W. The supporting unit 530 may be positioned within the treatment space 501. When viewed in a top plan view, the supporting unit 530 may be provided to have a circular shape. A top surface of the supporting unit 530 may have an area larger than that of the substrate W. The supporting unit 530 may be formed of a highly conductive material. Also, the supporting unit 530 may be formed of a good heat-resistant material.

The heating unit 540 may be configured to heat the substrate W loaded on the supporting unit 530. The heating unit 540 may be provided in the supporting unit 530. As an example, the heating unit 540 may be provided in the form of a heater. In some embodiments, a plurality of heaters may be provided in the supporting unit 530.

the gas supplying unit 550 may be configured to supply a gas onto the substrate W disposed in the treatment space 501. The gas may be a close-contact gas. As an example, the gas may contain hexamethyldisilazane. The gas may be used to change a surface property of the substrate W from hydrophilicity to hydrophobicity. The gas may be mixed with a carrier gas, and when it is supplied onto the substrate W, the mixture of the gas and the carrier gas may be supplied. The carrier gas may be or contain an inert or inactive gas. The inert or inactive gas may be, for example, a nitrogen gas.

The gas supplying unit 550 may include a gas supplying pipe 551 and a gas supplying line 553. The gas supplying pipe 551 may be connected to a center region of the upper chamber 511. The gas supplying pipe 551 may be used to supply a gas, which is transferred through the gas supplying line 553, to the substrate W. The gas supplying pipe 551 may be configured to allow the gas to be supplied toward the center region of the substrate W.

The exhausting element 570 may be used to exhaust an air from the treatment space 501 or a neighboring region of the treatment space 501. Here, the neighboring region of the treatment space 501 may refer to a region that is located between the upper and lower chambers 511 and 513 or near the contact surface.

The exhausting element 570 may include an outer exhausting line 571, an inner exhausting line 573, a combined line 575, and a decompressing element 577.

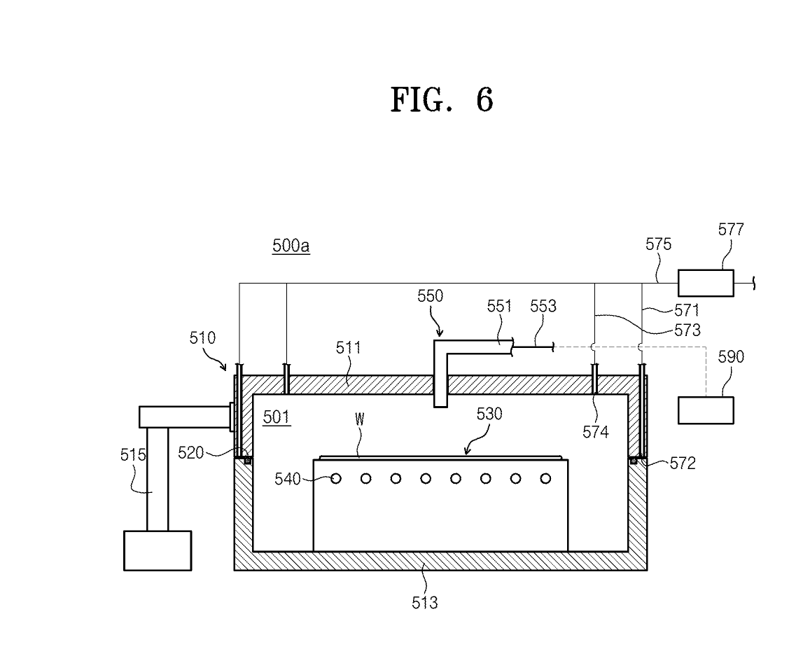

The outer exhausting line 571 may be connected to an outer exhausting hole 572. The outer exhausting hole 572 may be formed in or through the upper chamber 511 or the lower chamber 513. For example, the outer exhausting hole 572 may be formed in the lower chamber 513, as shown in FIG. 5. Alternatively, as shown in FIG. 6, the outer exhausting hole 572 may be formed in the upper chamber 511. The outer exhausting hole 572 may be provided at a position farther from the supporting unit 530, compared with the sealing element 520. The outer exhausting hole 572 may be a ring-shaped hole that is provided in the upper chamber 511. In certain embodiments, the outer exhausting hole 572 may be provided in the form of a plurality of holes. The outer exhausting line 571 may be connected to the outer exhausting hole 572 and may be used to exhaust an air from an outer region of the sealing element 520 which is the neighboring region of the treatment space 501. The number of the outer exhausting lines 571 may correspond to that of the outer exhausting holes 572.

The inner exhausting line 573 may be used to exhaust an air from the treatment space 501. The inner exhausting line 573 may be connected to an inner exhausting hole 574. The inner exhausting hole 574 may be provided in or through the upper chamber 511 or the lower chamber 513. For example, as shown in FIG. 5, the inner exhausting hole 574 may be formed through the lower chamber 513. Alternatively, as shown in FIG. 6, the inner exhausting hole 574 may be formed in the upper chamber 511. The inner exhausting hole 574 may be positioned on and connected to the treatment space 501. The inner exhausting hole 574 may be positioned outside the supporting unit 530, when viewed in a plan view. In certain embodiments, the exhausting element 570 may include a plurality of the inner exhausting holes 574. The number of the inner exhausting lines 573 may correspond to that of the inner exhausting holes 574.

The combined line 575 may be connected to both of the inner exhausting line 573 and the outer exhausting line 571. The combined line 575 may be used to exhaust a material in the inner exhausting line 573 and the outer exhausting line 571 to the outside of the substrate treatment apparatus 500a.

The decompressing element 577 may be used to realize a reduced pressure, when the exhausting process is performed on the treatment space 501 and the neighboring region of the treatment space 501. The decompressing element 577 may be provided on the combined line 575. In certain embodiments, a plurality of the decompressing elements 577 may be provided on the inner exhausting line 573 and the outer exhausting line 571, respectively. The decompressing element 577 may be or include, for example, a pump. However, any known decompressing device may also be used as the decompressing element 577.

The controller 590 may control the decompressing element 577 and the gas supplying unit 550. The controller 590 may control the gas supplying unit 550 and the decompressing element 577 so as to maintain the treatment space 501 at a low pressure during the process of treating the substrate W. For example, the low pressure may range from 50 pascal to 500 pascal. That is, the controller 590 may control the gas supplying unit 550 and the decompressing element 577 so as to maintain the treatment space 501 to a pressure of 50-500 pascal, during the process of treating the substrate W.

Hereinafter, a method of treating the substrate W using the substrate treatment apparatus 500a according to some embodiments of the inventive concept will be described.

The substrate W transferred from the outside may be loaded on the supporting unit 530. When the loading of the substrate W is finished, the process chamber 510 may be sealed by downwardly moving the upper chamber 511. Thereafter, a gas may be supplied into the treatment space 501 using the gas supplying unit 550. The gas may be a close-contact gas, which is or contains a hexamethyldisilazane gas or a mixture of a hexamethyldisilazane gas and a carrier gas. If the gas is supplied into the treatment space 501, the exhausting element 570 may be operated to exhaust an air or gas from the treatment space 501 or the neighboring region of the treatment space 501. Here, the decompressing element 577 and the gas supplying unit 550 may be controlled by the controller 590, so as to maintain the treatment space 501 at a pressure of 50-500 pascal.

Furthermore, the substrate W may be heated by the heating unit 540, during the process.

In the substrate treatment method according to some embodiments of the inventive concept, only a low pressure (e.g., of 50-500 Pa), not a vacuum pressure, may be needed for the process of supplying the close-contact gas onto the substrate W, and thus there may be no need to maintain the treatment space at a high vacuum level. Accordingly, there may be no need to use an expensive part for maintaining the treatment space at a high vacuum level. In addition, it may be possible to prevent the high vacuum level of the treatment space from being broken by the crack near the sealing element 520 or by the loading or unloading of the substrate W.

Furthermore, since the exhausting element 570 is used to exhaust an air from the treatment space 501 and the neighboring region of the treatment space 501, it may be possible to prevent or suppress fumes, which are produced in the substrate treating process, from affecting the substrate W. Since the low pressure (e.g., of 50-500 Pa) is maintained during the process and the exhausting process is performed, it may be possible to improve a process efficiency of the substrate treating process including a step of supplying a close-contact gas.

In the case where the treatment space 501 is maintained at the low pressure (e.g., of 50-500 Pa), it may be possible to prevent or suppress an air from flowing into the treatment space 501 from the outside. It may be possible to prevent or suppress an internal gas from leaking to the outside and from polluting the environment.

Hereinafter, referring to FIGS. 2 to 4, the bake chamber 420 may be used to perform a thermal treatment process on the substrate W. For example, the bake chambers 420 may be used to perform a pre-bake process, which is performed to heat the substrate W to a predetermined temperature or to remove an organic material or moisture from a surface of the substrate W before a photoresist coating process, a soft-bake process, which is performed on the substrate W after the photoresist coating process, or a cooling process, which is performed to cool down the substrate W after any heating process. The bake chamber 420 may include a cooling plate 421 or a heating plate 422. A cooling element 423 (e.g., a cooling water or a thermoelectric element) may be provided in the cooling plate 421. In addition, a heating element 424 (e.g., a heating line or a plated heating line) may be provided in the heating plate 422. In some embodiments, the heating element 424 (e.g., a thermoelectric element) may be provided in the heating plate 422. Each of the bake chambers 420 may be configured to have only one of the cooling plate 421 and the heating plate 422. In certain embodiments, at least one of the bake chambers 420 may be configured to have both of the cooling and heating plates 421 and 422.

The developing module 402 may be used to perform a developing process and a thermal treatment process. Here, the developing process may be performed to supply a developing solution for removing a portion of the photoresist material and to form patterns on the substrate W, and the thermal treatment process may be performed to heat and cool the substrate W before or after the developing process. The developing module 402 may include a developing chamber 460, a bake chamber 470, and a transfer chamber 480. The developing chamber 460, the bake chamber 470, and the transfer chamber 480 may be sequentially arranged in the second direction 14. Accordingly, the developing chamber 460 and the bake chamber 470 may be spaced apart from each other in the second direction 14, with the transfer chamber 480 interposed therebetween. In some embodiments, a plurality of the developing chambers 460 may be provided in each of the first and third directions 12 and 16.

The transfer chamber 480 may be provided to be parallel to the second buffer 330 of the first buffer module 300 in the first direction 12. A developing robot 482 and a guide rail 483 may be provided in the transfer chamber 480. The transfer chamber 480 may have a substantially rectangular shape. The developing robot 482 may be used to transfer the substrate W between the bake chambers 470, the developing chambers 460, and the second buffer 330 and the cooling chamber 350 of the first buffer module 300. The guide rail 483 may be provided to have a longitudinal direction parallel to the first direction 12. The guide rail 483 may be configured in such a way that the developing robot 482 is linearly moved in the first direction 12. The developing robot 482 may include a hand 484, an arm 485, a supporter 486, and a prop 487. The hand 484 may be fixedly connected to the arm 485. The arm 485 may be provided to have a stretchable structure, allowing the hand 484 to be moved in a horizontal direction. The supporter 486 may be provided to have a longitudinal direction parallel to the third direction 16. The arm 485 may be coupled to the supporter 486 so as to be linearly movable along the supporter 486 or in the third direction 16. The supporter 486 may be fixedly coupled to the prop 487. The prop 487 may be coupled to the guide rail 483 so as to be movable along the guide rail 483.

All of the developing chambers 460 may have the same structure. However, developing solutions to be used in the developing chambers 460 may be of different kinds. The developing chamber 460 may be used to remove a portion of the photoresist material from an irradiated region of the substrate W. Here, an irradiated portion of the protection layer may also be removed when the irradiated portion of the photoresist material is removed. In certain embodiments, depending on kinds of the material used, the photoresist material and the protection layer may be removed when they are not irradiated with light.

The developing chamber 460 may include a housing 461, a supporting plate 462, and a nozzle 463. The housing 461 may have a top-open cup-shaped structure. The supporting plate 462 may be positioned in the housing 461 and may support the substrate W. The supporting plate 462 may be provided to have a rotatable structure. The nozzle 463 may be configured to supply a developing solution onto the substrate W loaded on the supporting plate 462. The nozzle 463 may have a circular pipe shape and may be used to supply a developing solution toward a center of the substrate W. In certain embodiments, the nozzle 463 may have a length corresponding to a diameter of the substrate W and may have a slit-shaped ejecting hole. The developing chamber 460 may further include a nozzle 464 which is configured to supply a cleaning solution (e.g., a deionized water), and here, the cleaning solution may be used to clean a surface of the substrate W that has been treated with a developing solution.

The bake chamber 470 may be used to perform a thermal treatment process on the substrate W. For example, the bake chambers 470 may be used to perform a post-bake process for heating the substrate W before a developing process, a hard-bake process for heating the substrate W after the developing process, and a cooling process for cooling a heated substrate after each bake process. The bake chamber 470 may include a cooling plate 471 or a heating plate 472. A cooling element 473 (e.g., a cooling water or a thermoelectric element) may be provided in the cooling plate 471. A heating element 474 (e.g., a heating line or a thermoelectric element) may be provided in the heating plate 472. Each of the bake chambers 470 may be configured to have only one of the cooling plate 471 and the heating plate 472. In certain embodiments, at least one of the bake chambers 470 may be configured to have both of the cooling and heating plates 471 and 472.

As described above, in the coating and developing module 400, the coating module 401 and the developing module 402 may be provided to be spaced apart from each other. Also, when viewed in a top plan view, the coating module 401 and the developing module 402 may be provided to have the same chamber configuration.

The interface module 700 may be used to transfer the substrate W. The interface module 700 may include a frame 710, a first buffer 720, a second buffer 730, and an interface robot 740. The first buffer 720, the second buffer 730, and the interface robot 740 may be positioned within the frame 710. The first buffer 720 and the second buffer 730 may be stacked in a vertical direction and may be spaced apart from each other by a predetermined distance. The first buffer 720 may be disposed at a higher level than that of the second buffer 730.

The interface robot 740 may be disposed to be spaced apart from the first buffer 720 and the second buffer 730 in the second direction 14. The interface robot 740 may be used to transfer the substrate W between the first buffer 720, the second buffer 730, and the exposure system 900.

The first buffer 720 may be used to temporarily store the substrates W, to which the process has been performed, before the substrates W are transferred to the exposure system 900. The second buffer 730 may be used to temporarily store the substrates W, to which an exposure process using the exposure system 900 has been performed, before the substrates W are transferred to other place. The first buffer 720 may include a housing 721 and a plurality of supporters 722. The supporters 722 may be provided within the housing 721 and may be spaced apart from each other in the third direction 16. Each of the substrates W may be disposed on a corresponding one of the supporters 722. The housing 721 may include openings that are formed toward the interface robot 740 and a pre-treatment robot 632 and that allow the interface robot 740 and the pre-treatment robot 632 to load or unload the substrate W on or from the supporter 722 in the housing 721. The second buffer 730 may have a structure similar to that of the first buffer 720. In certain embodiments, the interface module 700 may be configured to have only the buffers and the robot, without a chamber for performing a predetermined process on a substrate.

The purge module 800 may be disposed in the interface module 700. In detail, the purge module 800 may be provided to be opposite to the first buffer 720, and thus, the interface robot 740 may be interposed between the first buffer 720 and the purge module 800. In certain embodiments, the purge module 800 may be provided at various positions (e.g., at a rear portion of the interface module 700, to which the exposure system 900 is connected, or at a side portion of the interface module 700). The purge module 800 may be used to perform a gas purge process and a rinse process on a substrate that is coated with a protection layer, and here, the protection layer may be used to prevent the photoresist material from being damaged in the interface module 700.

According to some embodiments of the inventive concept, a treatment space may be maintained at a constant pressure, during a process of supplying a close-contact gas onto a substrate, and this may make it possible to increase efficiency in a process of supplying a HMDS gas.

According to some embodiments of the inventive concept, an air may be exhausted from a treatment space and a neighboring region thereof, during the process of supplying the HMDS gas onto the substrate, and this may make it possible to increase efficiency in a process of supplying the close-contact gas.

According to some embodiments of the inventive concept, it may be possible to prevent or suppress an external air from flowing into the treatment space.

According to some embodiments of the inventive concept, it may be possible to prevent or suppress an internal gas in the treatment space from leaking to the outside and from polluting the environment.

While example embodiments of the inventive concepts have been particularly shown and described, it will be understood by one of ordinary skill in the art that variations in form and detail may be made therein without departing from the spirit and scope of the attached claims.

What is claimed is:

1. A substrate treatment apparatus, comprising:
a process chamber comprising an upper chamber and a lower chamber that are coupled to each other to define a treatment space;
a supporting unit provided within the treatment space to support a substrate; and
an exhausting element configured to exhaust an air from the treatment space or a neighboring region of the treatment space,
wherein the exhausting element comprises an outer exhausting line connected to an outer exhausting hole, and
the outer exhausting hole is formed in the upper or lower chamber and is connected to a contact surface, at which the upper and lower chambers are in contact with each other.

2. The substrate treatment apparatus of claim 1, further comprising a sealing element that is provided on the contact surface between the upper and lower chambers to hermetically seal the treatment space from an outside,
wherein the outer exhausting hole is formed at an outer position farther from the supporting unit, compared with the sealing element.

3. The substrate treatment apparatus of claim 2, wherein the exhausting element further comprises an inner exhausting line connected to an inner exhausting hole, and
the inner exhausting hole is formed in the upper or lower chamber and is used to exhaust an air from the treatment space.

4. The substrate treatment apparatus of claim 3, wherein the exhausting element further comprises:
a combined line connected to both of the inner and outer exhausting lines; and
a decompressing element provided on the combined line.

5. The substrate treatment apparatus of claim 4, further comprising:
a heating unit configured to heat the substrate loaded on the supporting unit; and
a gas supplying unit configured to supply a gas into the treatment space.

6. The substrate treatment apparatus of claim 5, further comprising a controller controlling the gas supplying unit and the decompressing element,
wherein the controller controls the gas supplying unit and the decompressing element to maintain the treatment space at a pressure of 50-500 pascal during a process of treating the substrate.

7. The substrate treatment apparatus of claim 6, wherein the gas to be supplied through the gas supplying unit contains hexamethyldisilazane (HMDS).

8. A substrate treatment apparatus comprising:
a process chamber comprising an upper chamber and a lower chamber that are coupled to each other to define a treatment space;
a supporting unit provided within the treatment space to support a substrate;
an exhausting element configured to exhaust an air from the treatment space or a neighboring region of the treatment space; and
a controller controlling the exhausting element,
wherein, during a process of supplying a hexamethyldisilazane gas, which is used as a close-contact gas, onto the substrate to treat the substrate, the controller controls the exhausting element to maintain the treatment space at a pressure of 50-500 pascal.

9. The substrate treatment apparatus of claim 8, further comprising a sealing element that is provided on a contact surface, at which the upper and lower chambers are in contact with each other, to hermetically seal the treatment space from an outside,
wherein the exhausting element comprises:
an outer exhausting line connected to an outer exhausting hole that is formed in the upper or lower chamber and is connected to the contact surface; and
an inner exhausting line connected to an inner exhausting hole that is formed in the upper or lower chamber and is used to exhaust an air from the treatment space,
wherein the outer exhausting hole is formed at an outer position farther from the supporting unit, compared with the sealing element.

10. The substrate treatment apparatus of claim 8, wherein the exhausting element further comprises:
a combined line connected to both of the inner and outer exhausting lines; and
a decompressing element provided on the combined line.

11. The substrate treatment apparatus of claim 8, further comprising:
a heating unit configured to heat the substrate loaded on the supporting unit; and
a gas supplying unit configured to supply the hexamethyldisilazane gas into the treatment space.

12. A method of treating a substrate, comprising
supplying a close-contact gas into a hermetically-sealed treatment space to treat a substrate disposed in the treatment space, the close-contact gas being a hexamethyldisilazane gas,
wherein, during the supplying of the close-contact gas, the treatment space or a neighboring region of the treatment space is decompressed to maintain the treatment space at a pressure of 50-500 pascal.

13. The method of claim 12, wherein the supplying of the close-contact gas comprises exhausting an air from the treatment space or a neighboring region of the treatment space,
the exhausting of the air from the neighboring region of the treatment space is performed through an outer exhausting line connected to an outer exhausting hole,
the outer exhausting hole is formed in an upper chamber or a lower chamber and is connected to a contact surface, at which the upper and lower chambers are in contact with each other, and
the treatment space is defined by the upper and lower chambers.

14. The method of claim 13, wherein the exhausting of the air from the treatment space is performed through an inner exhausting line that is connected to an inner exhausting hole, and
the inner exhausting hole is formed in the upper or lower chamber.

15. The method of claim 13, wherein the outer exhausting hole is connected to the contact surface between the upper and lower chambers and is formed at an outer position farther from the treatment space, compared with a sealing element configured to hermetically seal the treatment space from an outside.
